(19) United States
(12) Patent Application Publication
(10) Pub. No.: US 2025/0174976 A1
(43) Pub. Date: May 29, 2025

(54) SMART POWER SEMICONDUCTOR SWITCH DEVICE WITH SELF-DIAGNOSTIC FUNCTION AND METHOD THEREOF

(71) Applicant: Monolithic Power Systems, Inc., Kirkland, WA (US)

(72) Inventors: Di Han, San Jose, CA (US); Jian Jiang, Saratoga, CA (US); Eric Yang, Saratoga, CA (US); Michael Hsing, Saratoga, CA (US)

(21) Appl. No.: 18/520,963

(22) Filed: Nov. 28, 2023

(51) Int. Cl. H02H 3/04; G01R 31/26; H02H 7/20

(52) U.S. Cl. CPC H02H 3/044; G01R 31/2621; H02H 7/20

(57) ABSTRACT

Power switch device includes a wide-bandgap semiconductor switch, and a gate driver. The gate driver includes a driver circuit and a diagnostic circuit. The driver circuit is configured to provide a driver signal to control the wide-bandgap semiconductor switch. The diagnostic circuit is configured to sense an electrical characteristic of the wide-bandgap semiconductor switch, and perform a diagnostic test for the wide-bandgap semiconductor switch in response to the electrical characteristic of the wide-bandgap semiconductor switch.

### TECHNICAL FIELD

The present disclosure relates generally to power circuits, and more particularly but not exclusively to a power switch device.

### BACKGROUND OF THE INVENTION

For high-power applications such as vehicle powertrain, data center, cloud computing, and AI, wide bandgap (WBG) semiconductors are often used for power switching operations. These applications demands higher reliability and safety operation. As the WBG semiconductor switch degrades during operating over time, the failure of power switch over its lifetime has become one of the major concerns. Various failure detection and protection mode are accommodated under different operating conditions, such that catastrophic damage could be avoided during unexpected device failures. However, these design are often complicated and very costly.

Therefore, it is desirable to provide a way to simplify the system design while enhancing the reliability to ensure the safety operation of the WBG power switch.

### SUMMARY OF THE INVENTION

According to an embodiment of the present disclosure, a power switch device is provided. The power switch device includes a wide-bandgap semiconductor switch and a gate driver. The wide-bandgap semiconductor switch has a first terminal, a second terminal and a control terminal. The gate driver includes a driver circuit and a diagnostic circuit. The driver circuit is configured to provide a driver signal to control the wide-bandgap semiconductor switch. The diagnostic circuit is configured to sense an electrical characteristic of the wide-bandgap semiconductor switch, and perform a diagnostic test for the wide-bandgap semiconductor switch in response to the electrical characteristic of the wide-bandgap semiconductor switch.

According to another embodiment of the present disclosure, a power switch device is provided. The power switch device includes a wide-bandgap semiconductor switch and a gate driver. The wide-bandgap semiconductor switch has a first terminal, a second terminal and a control terminal. The gate driver includes a driver circuit and a fault detection circuit. The driver circuit is configured to provide a first driver signal to the control terminal of the wide-bandgap semiconductor switch. The fault detection circuit is configured to sense an electrical characteristic of the wide-bandgap semiconductor switch, and issue a fault signal when the electrical characteristic of the wide-bandgap semiconductor switch indicates the wide-bandgap semiconductor switch is damaged. The wide-bandgap semiconductor switch is integrated on a first die, and the gate driver is integrated on a second die.

According to yet another embodiment of the present disclosure, a method for controlling a wide-bandgap semiconductor switch is provided. The method includes the following actions. A diagnostic test for the wide-bandgap semiconductor switch is performed before the wide-bandgap semiconductor switch is operating. A health status of the wide-bandgap semiconductor switch is monitored when the wide-bandgap semiconductor switch is operating. When the diagnostic test fails, a fault signal is issued to disable the operation of the wide-bandgap semiconductor switch. A warning signal is issued in response to the health status of the wide-bandgap semiconductor switch.

### BRIEF DESCRIPTION OF THE DRAWINGS

The present disclosure can be further understood with reference to the following detailed description and appended drawings, where like elements are provided with like reference numerals. These drawings are only for illustration purpose, thus may only show part of the devices and are not necessarily drawn to scale.

FIG. 1 is a schematic block diagram of a power switch device in accordance with an embodiment of the present disclosure.

FIG. 2 is a schematic block diagram of a power switch device in accordance with another embodiment of the present disclosure.

FIGS. 3A-3E schematically show several composite cascode structures of JFET and MOSFET in accordance with some embodiments of the present disclosure.

FIG. 4 is a schematic block diagram of a power switch device in accordance with yet another embodiment of the present disclosure.

FIG. 5 is a schematic block diagram of a power switch device in accordance with yet another embodiment of the present disclosure.

FIG. 6 is a flowchart of a method for controlling a wide-bandgap semiconductor switch in accordance with an embodiment of the present disclosure.

FIG. 7 is a flowchart of a method for controlling a wide-bandgap semiconductor switch in accordance with an embodiment of the present disclosure.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the phrases “in one embodiment”, “in some embodiments”, “in one implementation”, and “in some implementations” as used includes both combinations and sub-combinations of various features described herein as well as variations and modifications thereof. These phrases used herein do not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

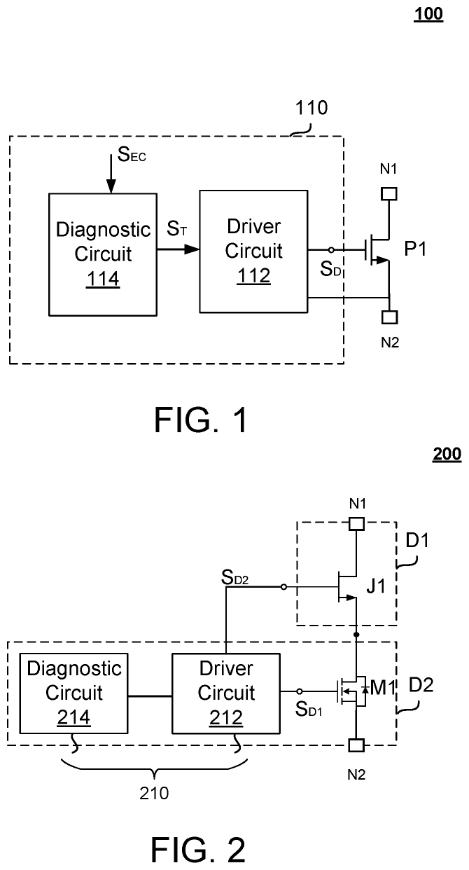

FIG. 1 is a schematic block diagram of a power switch device 100 in accordance with an embodiment of the present disclosure. As shown in FIG. 1, the power switch device 100 includes a wide-bandgap (WBG) semiconductor switch P1 and a gate driver 110. In one implementation, the WBG semiconductor switch P1 includes silicon carbide (SiC) material. In another implementation, the WBG semiconductor switch P1 includes gallium nitride (GaN) material. In some other implementations, the WBG semiconductor switch P1 includes WBG semiconductor materials having a bandgap energy greater than a bandgap energy of the silicon, such as diamond, III-V semiconductor materials, and II-VI semiconductor materials. III-V semiconductor materials may include essentially one element from group III and one element from group V, for instance, boron nitride (BN), aluminum nitride (AlN), aluminium phosphide (AIP), gallium phosphide (GaP), and gallium arsenide (GaAs). II-VI semiconductor materials may include a metal from either group 2 or 12 of the periodic table and a nonmetal element from group VI, for instance, cadmium sulfide (CdS), cadmium telluride (CdTE), zinc oxide (ZnO), zinc sulfide (ZnS), and zinc selenide (ZnSe).

In one embodiment, the WBG semiconductor switch P1 includes a Metal-Oxide-Semiconductor Field-Effect Transistor (MOSFET) having a first terminal (e.g., drain), a second terminal (e.g., source) and a control terminal (e.g., gate). In another embodiment, the WBG semiconductor switch P1 includes a Junction Field-Effect Transistor (JFET). In yet another embodiment, the WBG semiconductor switch P1 includes a High Electron Mobility Transistor (HEMT).

In one implementation, the gate driver 110 is manufactured on a silicon (Si) substrate, and the WBG semiconductor switch P1 is manufactured on a silicon carbide (SiC) substrate. The gate driver 110 includes a driver circuit 112 and a diagnostic circuit 114. The driver circuit 112 is configured to provide a driver signal Sp to control the WBG semiconductor switch P1. In this embodiment, the WBG semiconductor switch P1 is a MOSFET, and the driver signal S_{D} is provided to the gate terminal of the MOSFET P1. The diagnostic circuit 114 is configured to sense an electrical characteristic S_{EC} of the WBG semiconductor switch P1.

The electrical characteristic S_{EC} of the WBG semiconductor switch P1 may include, but not limited to, a gate to source leakage current (I_{GSS}), a drain to source leakage current (I_{DSS}), a pinch-off voltage (V_{P}), a gate threshold (V_{GS(TH)}), an on-resistance (R_{DS(on)}), and a body diode voltage drop of the WBG semiconductor switch P1. In another embodiment, the electrical characteristic further includes an input capacitance (Ciss), an output capacitance (Coss), and a reverse transfer capacitance (Crss). In yet another embodiment, the electrical characteristic further includes a drain to source voltage (V_{DS}). In some embodiments, the electrical characteristic further includes a reverse recovery charge (Q_{RR}), a total gate charge (Q_{G}), a gate to drain charge (Q_{GD}), and a gate to source charge (Q_{GS}). In some other embodiments, the electrical characteristic further includes a gate resistance (R_{G}).

The diagnostic circuit 114 is configured to perform a diagnostic test for the WBG semiconductor switch P1 in response to the electrical characteristic S_{EC} of the WBG semiconductor switch P1. For example, the diagnostic circuit 114 compares the sensed electrical characteristic with predetermined values, and provides the diagnostic test result S_{T} to the driver circuit 112. In one embodiment, the diagnostic test result indicates a failure event that may damage the WBG semiconductor switch P1, which could be critical to the system operation. Accordingly, the driver circuit 112 may turn off the WBG semiconductor switch P1 when the diagnostic test fails. For instance, the gate leakage current (I_{GSS} or I_{DSS}) may vary with the Vgs and Vds voltages, and the high leakage may damage the WBG semiconductor switch P1. The diagnostic circuit 114 determines that the gate leakage current (I_{GSS} or I_{DSS}) exceeds a threshold, which means that a failure event occur, the diagnostic circuit 114 provides the diagnostic test result S_{T} to the driver circuit 112 to disable the operation of the WBG semiconductor switch P1.

In one embodiment, the diagnostic test is performed upon the system startup or initialization stage. In another embodiment, the diagnostic test is performed when the WBG semiconductor switch P1 is operating (e.g., during switching).

In one embodiment, the power switch device 100 is used in a switching mode power supply. For example, the power switch device 100 is one of the switches in a boost converter. In another example, the power switch device 100 is one of the switches in buck converter. In yet another example, the power switch device 100 is one of the switches in a buck-boost converter. In one implementation, the power switch device 100 is one of the switches in a switched-capacitor circuit. In another implementation, the power switch device 100 is a load switch. In other instances, the power switch device 100 is one of the switches in an LLC converter. In some other instances, the power switch device 100 is one of the switches in a bridge circuit (half-bridge or full-bridge). In some other implementations, the power switch device 100 is a synchronous rectifier. In some embodiments, the power switch device 100 may include more WBG semiconductor switches to function as the above-mentioned switching mode power supply. Accordingly, the driver circuit 112 provides the corresponding driving signal to the WBG semiconductor switches. The diagnostic circuit 114 senses the electrical characteristic S_{EC} of the WBG semiconductor switches, and perform the diagnostic test for the WBG semiconductor switches according to the operation conditions of the switching mode power supply.

FIG. 2 is a schematic block diagram of a power switch device 200 in accordance with another embodiment of the present disclosure. In the embodiment as shown in FIG. 2, the WBG semiconductor switch includes a JFET J1. The power switch device 200 further includes a gate driver 210. The gate driver 210 includes a driver circuit 212 and a diagnostic circuit 214. In this embodiment, the JFET J1 is in serially connected with a cascode switch, for instance, a MOSFET M1. In one embodiment, the cascode switch includes a non-WBG (e.g., silicon material) device. The cascode switch includes, a bipolar transistor (BJT), a field-effect transistor (FET), or an insulated-gate bipolar transistor (IGBT), a MOSFET, a HEMT, a JFET, a Gate Turn-off Thyristor (GTO) or a Gate-Commutated Thyristor (GCT). In one implementation, the power switch device 200 is an integrated circuit (IC), for instance, the JFET J1 is integrated on a SiC die D1, and the gate driver 210 and the MOSFET M1 are integrated on a Si die D2 and are co-packaged with the SiC die. In another implementation, the JFET J1 is integrated on an IC, and the gate driver 210 and the MOSFET M1 are integrated in another IC.

Specifically, the first terminal (e.g., drain) of the JFET J1 is coupled to a first node N1, the second terminal (e.g., source) of the JFET J1 is coupled to the first terminal (e.g., drain) of the cascode MOSFET M1, and the second t terminal (e.g., source) of the cascode MOSFET M1 is coupled to a second node N2. The SiC JFET J1 is a high voltage normally-on (depletion mode) device, while the Si MOSFET M1 is a low voltage normally-off (enhancement mode) device. For instance, the JFET is able to sustain high voltage level higher than 100 volts; and the MOSFET operates at a voltage level lower than 100 volts.

In one embodiment, the gate terminal of the SiC JFET J1 is coupled to the source terminal of the Si MOSFET M1. The driver signal SD1 is provided to the control terminal of the Si MOSFET M1 to turn on or turn off the Si MOSFET M1, and the operation of the SiC JFET J1 is controlled according to the operation of the Si MOSFET M1. When the Si MOSFET M1 is turned off, the source terminal of the SiC JFET J1 (i.e., the drain to source (V_{DS}) of the Si MOSFET M1) is at a high voltage level, and therefore the gate to source voltage of the JFET J1 is reverse biased and reaches a pinch-off voltage of the JFET, causing the JFET J1 to be OFF. When the Si MOSFET M1 is turned on, the SiC JFET J1 is also turned on.

In another embodiment, the gate terminal of the SiC JFET J1 is directly controlled by the driver signal SD1 (e.g., a negative voltage) via the driver circuit 212, and the Si MOS is normally-on.

Whether the JFET J1 is directly controlled or indirectly controlled via the cascode MOSFET M1, the gate leakage current (I_{GSS} or I_{DSS}) is likely to occur. When the diagnostic circuit 214 determines that the gate leakage current (I_{GSS} or I_{DSS}) exceeds a threshold, the diagnostic circuit 214 issues a command to the driver circuit 212 to turn off the JFET J1 by the driver signal SD1 or the driver signal SD2.

For instance, the electrical characteristic S_{EC} of the WBG semiconductor switch P1 may include, but not limited to, a gate to source leakage current (I_{CSS}), a drain to source leakage current (I_{DSS}), a pinch-off voltage (V_{P}), a gate threshold (V_{GS(TH)}), an on-resistance (R_{DS(on)}), and a body diode voltage drop of the WBG semiconductor switch P1. In one embodiment, when the fault event occurs, the driver circuit is further configured to disable the operation (e.g., turn off) of the WBG semiconductor switch P1.

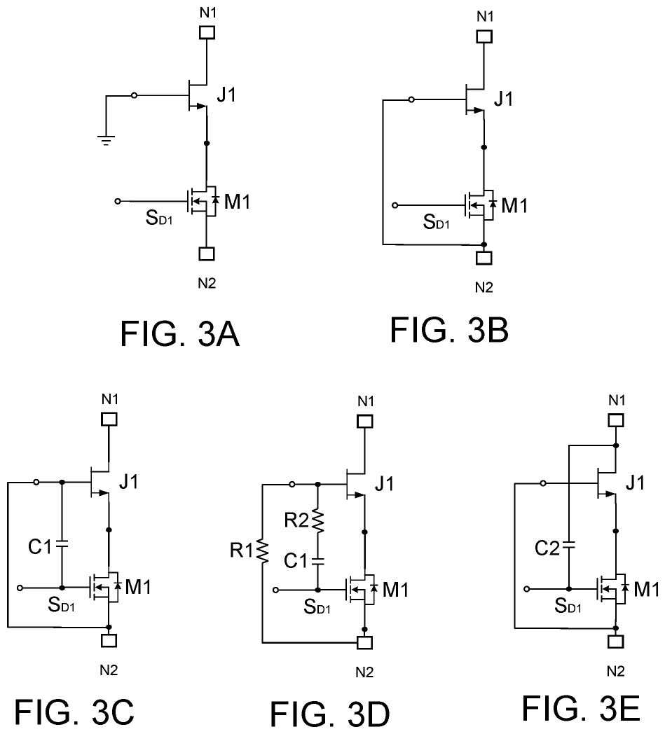

FIGS. 3A-3D schematically show several composite cascode structures of JFET J1 and MOSFET M1 in accordance with some embodiments of the present disclosure. As shown in FIG. 3A, the first terminal (e.g., drain) of the JFET J1 is coupled to a first node N1, the second terminal (e.g., source) of the JFET J1 is coupled to the first terminal (e.g., drain) of the cascode MOSFET M1, and the second t terminal (e.g., source) of the cascode MOSFET M1 is coupled to a second node N2. In this embodiment, the gate terminal of the JFET J1 is coupled to the ground, and the driver signal SD1 is provided to the control terminal (e.g., gate) of the MOSFET M1, and the operation of the JFET J1 is controlled according to the operation of the MOSFET M1.

In one embodiment as shown in FIG. 3B, the gate terminal of the JFET J1 is coupled to the source terminal of the MOSFET M1, and the operation of the JFET J1 is controlled according to the operation of the MOSFET M1.

In one embodiment as shown in FIG. 3C, the gate terminal of the JFET J1 is coupled to the gate terminal of the MOSFET M1 via a capacitor C1.

In one embodiment as shown in FIG. 3D, the gate terminal of the JFET J1 is coupled to the source terminal of the MOSFET M1 via a resistor R1. The gate terminal of the JFET J1 is further coupled to the gate terminal of the MOSFET M1 via a capacitor C1 and a resistor R2.

In one embodiment as shown in FIG. 3E, the gate terminal of the JFET J1 is coupled to the source terminal of the MOSFET M1, and the drain terminal of the JFET J1 is coupled to the source terminal of the MOSFET M1.

However, the present disclosure is not limited thereto. The composite cascode structures of JFET J1 and MOSFET M1 may have one or more resistors, capacitors and other components and circuits coupled to the source, gate, or drain terminal of the JFET J1 or the MOSFET M1. These components, circuits, and the composite cascode structures of JFET J1 and MOSFET M1 may have different driving conditions for the JFET J1. However, the diagnostic circuit 214 performs the diagnostic tests for the WBG JFET J1 with different composite cascode structures according to the corresponding driving conditions, and provides the diagnostic test result to the driver circuit 212 to ensure the safety operation of the JFET J1, and prevent damage to the JFET J1.

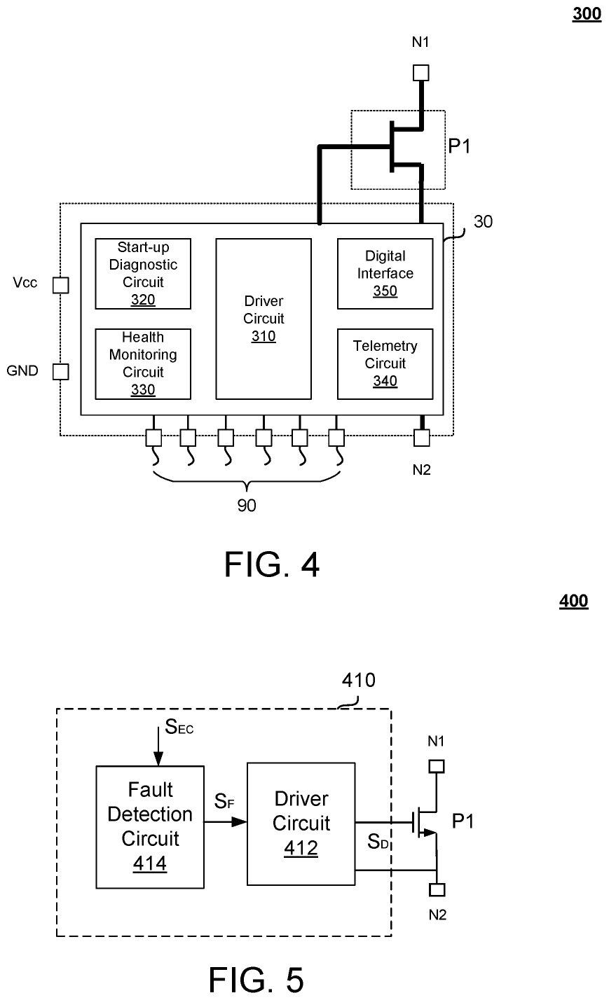

FIG. 4 is a schematic block diagram of a power switch device 300 in accordance with yet another embodiment of the present disclosure. In this embodiment, the gate driver 30 includes a driver circuit 310, a start-up diagnostic circuit 320, a health monitoring circuit 330, a telemetry circuit 340, and a digital interface 350.

In one embodiment, the power switch device 300 is an IC having multiple pins. For instance, a Vcc pin is configured to receive a power supply voltage, a GND pin is configured to be coupled to a reference ground, a N1 pin is coupled to a first terminal (e.g., drain) of the WBG semiconductor switch P1, and a N2 pin is coupled to a second terminal (e.g., source) of the WBG semiconductor switch P1. In some embodiments, the power switch device 300 further includes one or more pins 90 configured to receive and/or transmit enable signals, sense signals, monitor signals, control signals and/or data.

The driver circuit 310 is configured to provide a driver signal to control the WBG semiconductor switch P1. In this embodiment, the WBG semiconductor switch P1 is a JFET. In one embodiment, the driver signal is provided to the gate terminal of the JFET P1. In another embodiment, the driver signal is provided to the gate terminal of the cascode transistor in serially connected with the JFET P1.

The start-up diagnostic circuit 320 is configured to sense the electrical characteristic of the WBG semiconductor switch P1 before the wide-bandgap semiconductor switch is operating. For example, a diagnostic test is performed upon the system startup or initialization stage. During the diagnostic test, the start-up diagnostic circuit 320 compares each test item (i.e., the sensed electrical characteristic) with a standard. In one embodiment, the standard may be a value or a range defined by the user. In another embodiment, the standard may be determined according to the data obtained from production test, which could be stored in a memory.

When the sensed electrical characteristic fails to meet the standard (e.g., exceeds the maximum value, the minimum value, or is out of range of the target value), that is, the corresponding test item fails, and thus the start-up diagnostic circuit 320 issues a fault signal. In some embodiments, the power switch device 300 further report the fault signal indicating the test result to a system controller, such as a Micro-Controller Unit (MCU) or a Digital Signal Processor (DSP), and wait for the system controller to decide the next action. In some embodiments, for some test item (i.e., the sensed electrical characteristic), the fault signal indicates that the WBG semiconductor switch P1 is damaged, which could be critical to the system operation. Accordingly, the driver circuit 310 disables the operation of the WBG semiconductor switch P1 when the fault signal is issued.

The health monitoring circuit 330 is configured to sense the electrical characteristic of the WBG semiconductor switch P1 when the WBG semiconductor switch P1 is operating (e.g., during switching). For example, the health monitoring action is performed on a cycle-by-cycle basis. During the WBG semiconductor switch P1 is operating, the health monitoring circuit 330 monitors the health status of the WBG semiconductor switch P1. In one example, the health status indicates whether the WBG semiconductor switch P1 is damaged. In another example, the health status indicates the remaining lifetime of the WBG semiconductor switch P1. The health status and related condition and parameters could be defined by the user.

The health monitoring circuit 330 compares the sensed electrical characteristic with a standard. In one embodiment, the standard may be a value or a range defined by the user. In another embodiment, the standard may be determined according to the data obtained from production test, which could be stored in a memory. In some embodiments, the standard may be historical data, which could be stored in a memory.

When the sensed electrical characteristic fails to meet the standard (e.g., exceeds the maximum value, the minimum value, or is out of range of the target value), the health monitoring circuit 330 issues a warning signal. In one embodiment, the health monitoring circuit 330 further determines whether a failure event occurs according to the sensed electrical characteristic. For some test item, the sensed electrical characteristic indicates a failure event occurs, for example, the WBG semiconductor switch P1 may be damaged, and thus the health monitoring circuit 330 issues a shutdown signal. Accordingly, the driver circuit 310 disables the operation (e.g., turn off) of the WBG semiconductor switch P1 when the shutdown signal is issued.

In another embodiment, the health monitoring circuit 330 predicts the remaining lifetime of the WBG semiconductor switch P1 according to the sensed electrical characteristic. For example, the health monitoring circuit 330 compares the monitored data with historical data. As the degradation of the WBG semiconductor switch P1 operating over time, when the predicted remaining lifetime of the WBG semiconductor switch P1 is less than a threshold Th1, the health monitoring circuit 330 issues a warning signal to the driver circuit. In another embodiment, the warning signal is sent to the external system controller. In some embodiments, when the predicted remaining lifetime of the WBG semiconductor switch P1 is too short (less than a threshold Th2), the WBG semiconductor switch P1 may be damaged, the health monitoring circuit 330 issues a shutdown signal. Accordingly, the driver circuit 310 disables the operation (e.g., turn off) of the WBG semiconductor switch P1 when the shutdown signal is issued.

The telemetry circuit 340 is configured to receive the electrical characteristic of the WBG semiconductor switch P1 and transmit to external controller though a digital interface 350. For example, the end application or the system controller may require the monitored voltage, current, temperature, and other parameters for real time processing to control the system applications. In one embodiment, the telemetry circuit 340 includes sensors to monitor data including, but not limited to, a drain to source voltage, a current during on-state, a gate to source voltage, a current during switching transitions, a WBG die temperature, and a Si die temperature. Similarly, when an over voltage condition, an over current condition, or an over temperature condition is detected, the driver circuit 310 may soft turn-off the WBG semiconductor switch P1 and the telemetry circuit 340 may send a fault signal or a warning signal.

The digital interface 350 includes PMBus, I2C or SPI and others communication between the power switch device 30 and the external digital controller. The digital interface 350 is configured to receive a diagnostic test configuration. The diagnostic test configuration may include, but not limited to, conditions and standards including thresholds or target values of the test item, setting of various performance specs (such as slew rate), eligible range of the diagnostic/health monitor parameters, predicted remaining lifetime, real-time data of the sensed quantities, triggering thresholds of failure event and/or protection event (e.g., overcurrent, over voltage, over temperature events), and desired actions of each qualified event. In one embodiment, the digital interface 350 further includes a graphical user interface (GUI) for the end user to configure the test item and monitor the real-time electrical characteristic measurements.

FIG. 5 is a schematic block diagram of a power switch device 400 in accordance with yet another embodiment of the present disclosure. As shown in FIG. 4, the power switch device 400 includes a WBG semiconductor switch P1 and a gate driver 410. The gate driver 410 includes a driver circuit 412 and a fault detection circuit 414. The driver circuit 412 is configured to provide a driver signal Sp to control the WBG semiconductor switch P1. The fault detection circuit 414 is configured to sense an electrical characteristic S_{EC} of the WBG semiconductor switch P1. The fault detection circuit 414 is further configured to issue a fault signal SF when the sensed electrical characteristic S_{EC} of the WBG semiconductor switch P1 indicates the WBG semiconductor switch P1 is damaged.

For instance, the electrical characteristic S_{EC} of the WBG semiconductor switch P1 may include, but not limited to, a gate to source leakage current (I_{GSS}), a drain to source leakage current (I_{DSS}), a pinch-off voltage (V_{P}), a gate threshold (V_{GS(TH)}), an on-resistance (R_{DS(on)}), and a body diode voltage drop of the WBG semiconductor switch P1. In one embodiment, when the fault event occurs, the driver circuit is further configured to disable the operation (e.g., turn off) of the WBG semiconductor switch P1.

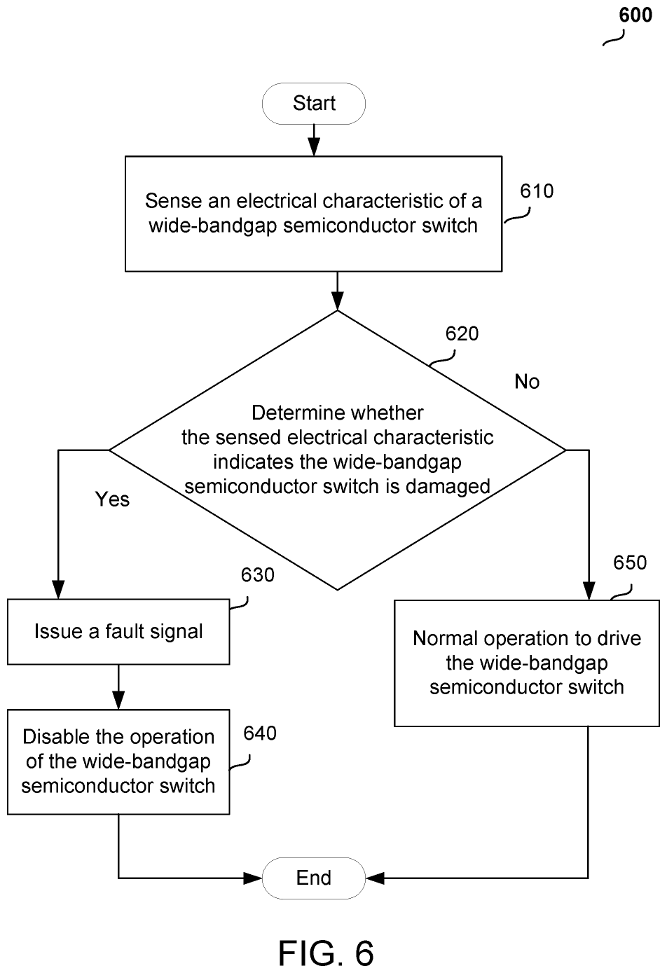

FIG. 6 is a flowchart of a method 600 for controlling a wide-bandgap semiconductor switch in accordance with an embodiment of the present disclosure. The method may be performed by a power switch device 100, 200, 300, 400 as shown in FIGS. 1-2, 4-5. The method includes the following actions. In action 610, an electrical characteristic of a wide-bandgap semiconductor switch is sensed. In action 620, whether the sensed electrical characteristic indicates the wide-bandgap semiconductor switch is damaged is determined. When it is determined that the wide-bandgap semiconductor switch is damaged, the action 630 is performed. In action 630, a fault signal is issued. In one embodiment, when the fault signal is issued, action 640 is performed. In action 640, the operation of the wide-bandgap semiconductor switch is disabled (e.g., by soft turn-off). Alternatively, when no fault event occurs, action 650 is performed. That is, the wide-bandgap semiconductor switch operate normally according to the drive signal.

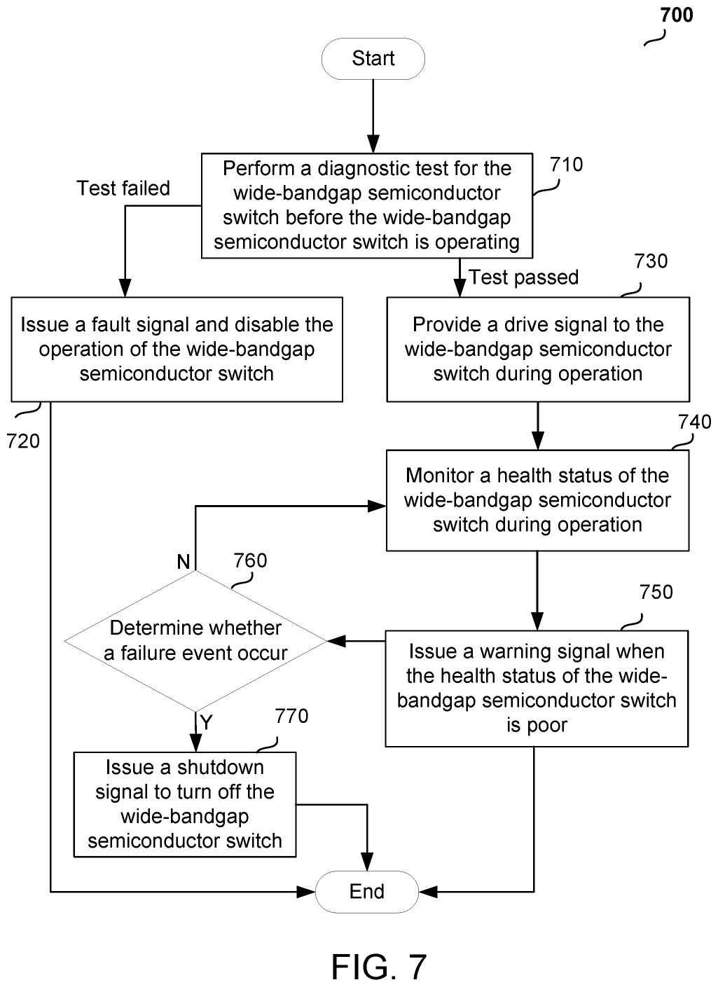

FIG. 7 is a flowchart of a method 700 for controlling a wide-bandgap semiconductor switch in accordance with an embodiment of the present disclosure. The method may be performed by a power switch device 100, 200, 300, 400 as shown in FIGS. 1-2, 4-5. The method includes the following actions. In action 710, a diagnostic test for the wide-bandgap semiconductor switch is performed before the wide-bandgap semiconductor switch is operating. When the diagnostic test fails, a fault signal is issued to disable the operation of the wide-bandgap semiconductor switch as shown in action 720. Alternatively, when the diagnostic test passes, a drive signal is provided to the wide-bandgap semiconductor switch during operation as shown in action 730.

Afterwards, during operation, the power switch device keep monitoring the health status of the wide-bandgap semiconductor switch. For example, action 740 is performed, a health status of the wide-bandgap semiconductor switch is monitored during operation. For example, the health status is determined according to the electrical characteristic of the wide-bandgap semiconductor switch. When the health status indicates the wide-bandgap semiconductor switch is poor (e.g., damaged), a warning signal is issued in action 750.

In one embodiment, action 760 is performed to determine whether a failure event occur during operation in response to the sensed electrical characteristic. When a failure event occur, a shutdown signal is performed to turn off the wide-bandgap semiconductor switch as shown in action 770.

In some embodiments, during action 740, the remaining lifetime of the wide-bandgap semiconductor switch is predicted according to the sensed electrical characteristic. When the predicted remaining lifetime of the wide-bandgap semiconductor switch is less than a threshold, a warning signal is issued. In another example, when the predicted remaining lifetime is too short, a shutdown signal is issued to turn off the wide-bandgap semiconductor switch.

Although the flowchart of FIGS. 6-7 shows a sequential action. It is obvious to persons skilled the art that these actions could be performed in any order.

Based on the above, the present disclosure provides various power switch device and control method thereof. The smart power switch device in the present disclosure provides self-diagnostic function to sense the electrical characteristic of the WBG semiconductor switch, and issue a warning signal or a fault signal to disables the operation of the WBG semiconductor switch. Furthermore, the health status of the WBG power semiconductor switch is monitored during operation to determine whether a failure event occurs according to the sensed electrical characteristic, such that the WBG semiconductor switch could be turned off safely to prevent damage to the WBG semiconductor switch is damaged. Moreover, the remaining lifetime of the wide-bandgap semiconductor switch is predicted according to the sensed electrical characteristic. As a result, the wide-bandgap semiconductor switch operate safely and turned off safely before the wide-bandgap semiconductor switch is damaged.

It will be appreciated by persons skilled in the art that the present disclosure is not limited to what has been particularly shown and described herein above. Rather the scope of the present disclosure is defined by the claims and includes both combinations and sub-combinations of the various features described hereinabove as well as variations and modifications thereof which would occur to persons skilled in the art upon reading the foregoing description and which are not in the prior art.

What is claimed is:

1. A power switch device, comprising:
a wide-bandgap semiconductor switch having a first terminal, a second terminal and a control terminal; and
a gate driver, comprising:
a driver circuit configured to provide a driver signal to control the wide-bandgap semiconductor switch; and
a diagnostic circuit configured to sense an electrical characteristic of the wide-bandgap semiconductor switch, and perform a diagnostic test for the wide-bandgap semiconductor switch in response to the electrical characteristic of the wide-bandgap semiconductor switch.

2. The power switch device of claim 1, wherein the diagnostic circuit comprises:
a start-up diagnostic circuit configured to sense the electrical characteristic of the wide-bandgap semiconductor switch before the wide-bandgap semiconductor switch is operating, compare the electrical characteristic with a first standard, and issue a fault signal when the electrical characteristic fails to meet the first standard.

3. The power switch device of claim 2, wherein when the fault signal is issued, the driver circuit is further configured to disable the operation of the wide-bandgap semiconductor switch.

4. The power switch device of claim 1, wherein the diagnostic circuit comprises:
a health monitoring circuit configured to sense the electrical characteristic of the wide-bandgap semiconductor switch when the wide-bandgap semiconductor switch is operating, compare the electrical characteristic with a second standard, and issue a warning signal when the electrical characteristic fails to meet the second standard.

5. The power switch device of claim 4, wherein the health monitoring circuit is further configured to determine whether a failure event occurs according to the electrical characteristic of the wide-bandgap semiconductor switch, and issue a shutdown signal when the failure event occurs; wherein when the shutdown signal is issued, the driver circuit is further configured to turn off the wide-bandgap semiconductor switch.

6. The power switch device of claim 4, wherein the health monitoring circuit is further configured to predict a remaining lifetime of the wide-bandgap semiconductor switch according to the sensed electrical characteristic, and issues a shutdown signal to turn off the wide-bandgap semiconductor switch when the predicted remaining lifetime of the wide-bandgap semiconductor switch is less than a threshold.

7. The power switch device of claim 1, wherein the gate driver further comprises:
a telemetry circuit configured to receive the electrical characteristic of the wide-bandgap semiconductor switch, and transmit the electrical characteristic of the wide-bandgap semiconductor switch to a controller.

8. The power switch device of claim 1, wherein the gate driver further comprises:
a digital interface configured to receive a diagnostic test configuration.

9. The power switch device of claim 1, further comprising:
a cascode switch having a first terminal, a second terminal and a control terminal, wherein the first terminal of the cascode switch is coupled to the second terminal of the wide-bandgap semiconductor switch;
wherein the driver circuit is further configured to provide the driver signal to the control terminal of the cascode switch, the cascode switch is turned on or turned off in response to the driver signal, and the operation of the wide-bandgap semiconductor switch is controlled according to the operation of the cascode switch.

10. The power switch device of claim 1, wherein the wide-bandgap semiconductor switch is integrated on a first die, and the gate driver is integrated on a second die.

11. A power switch device, comprising:
a wide-bandgap semiconductor switch having a first terminal, a second terminal and a control terminal; and
a gate driver, comprising:
a driver circuit configured to provide a first driver signal to the control terminal of the wide-bandgap semiconductor switch; and
a fault detection circuit configured to sense an electrical characteristic of the wide-bandgap semiconductor switch, and issue a fault signal when the electrical characteristic of the wide-bandgap semiconductor switch indicates the wide-bandgap semiconductor switch is damaged;
wherein the wide-bandgap semiconductor switch is integrated on a first die, and the gate driver is integrated on a second die.

12. The power switch device of claim 11, wherein when the electrical characteristic of the wide-bandgap semiconductor switch indicates the wide-bandgap semiconductor switch is damaged, the driver circuit is further configured to disable the operation of the wide-bandgap semiconductor switch.

13. The power switch device of claim 11, wherein the electrical characteristic of the wide-bandgap semiconductor switch includes a gate to source leakage current of the wide-bandgap semiconductor switch.

14. The power switch device of claim 11, wherein the electrical characteristic of the wide-bandgap semiconductor switch includes a drain to source leakage current of the wide-bandgap semiconductor switch.

15. The power switch device of claim 11, wherein the electrical characteristic of the wide-bandgap semiconductor switch includes a pinch-off voltage of the wide-bandgap semiconductor switch.

16. The power switch device of claim 11, wherein the electrical characteristic of the wide-bandgap semiconductor switch includes a gate threshold of the wide-bandgap semiconductor switch.

17. The power switch device of claim 11, wherein the electrical characteristic of the wide-bandgap semiconductor switch includes an on-resistance of the wide-bandgap semiconductor switch.

18. The power switch device of claim 11, wherein the electrical characteristic of the wide-bandgap semiconductor switch includes a body diode voltage drop of the wide-bandgap semiconductor switch.

19. A method for controlling a wide-bandgap semiconductor switch, comprising:
performing a diagnostic test for the wide-bandgap semiconductor switch before the wide-bandgap semiconductor switch is operating; and
monitoring a health status of the wide-bandgap semiconductor switch when the wide-bandgap semiconductor switch is operating;
wherein when the diagnostic test fails, a fault signal is issued to disable the operation of the wide-bandgap semiconductor switch;
a warning signal is issued in response to the health status of the wide-bandgap semiconductor switch.

20. The method of claim 19, wherein when the health status indicates a remaining lifetime of the wide-bandgap semiconductor switch is less than a threshold, a shutdown signal is issued to turn off the wide-bandgap semiconductor switch.
